(19) United States
(12) Patent Application Publication
(10) Pub. No.: US 2024/0421124 A1
(43) Pub. Date: Dec. 19, 2024

(54) MANUFACTURING METHOD OF ELECTRONIC PACKAGE AND ELECTRONIC PACKAGE

(71) Applicant: VIA Technologies, Inc., New Taipei City (TW)

(72) Inventors: Wen-Yuan Chang, New Taipei City (TW); Wei-Cheng Chen, New Taipei City (TW); Chen-Yueh Kung, New Taipei City (TW)

(73) Assignee: VIA Technologies, Inc., New Taipei City (TW)

(21) Appl. No.: 18/476,279

(22) Filed: Sep. 27, 2023

(30) Foreign Application Priority Data
Jun. 16, 2023 (TW) 112122519

(51) Int. Cl. H01L 25/065; H01L 23/00; H01L 23/498; H01L 23/538

(52) U.S. Cl. CPC H01L 25/0655; H01L 23/49816; H01L 23/5381; H01L 23/5383; H01L 24/06; H01L 24/08; H01L 24/16; H01L 25/50; H01L 2224/06177; H01L 2224/08145; H01L 2224/16227

(57) ABSTRACT

A manufacturing method of an electronic package includes the following steps. Multiple chips and a base dielectric layer are provided. A back surface of each chip is fixed to a back surface temporary carrier via a back surface temporary bonding layer. A base dielectric layer surrounds each chip and covers the back surface temporary bonding layer. A material of the base dielectric layer includes a silicate composite material. At least one bridge element is installed on the adjacent chips. An intermediate dielectric layer covering the base dielectric layer, the chips, and the bridge element is formed. Multiple intermediate conductive vias and a redistribution structure are respectively formed on the chips and the intermediate dielectric layer. Multiple conductive bumps are formed on the redistribution structure. The back surface temporary bonding layer and the back surface temporary carrier are removed. An electronic package produced by the manufacturing method is also provided.

### CROSS-REFERENCE TO RELATED APPLICATION

This application claims the priority benefit of Taiwan application serial no. 112122519, filed on Jun. 16, 2023. The entirety of the above-mentioned patent application is hereby incorporated by reference herein and made a part of this specification.

### BACKGROUND

### Technical Field

The disclosure relates to an electronic component, and in particular relates to a manufacturing method of an electronic package and an electronic package.

### Description of Related Art

There are many types of electronic packaging technologies currently used for multi-chips, one of which is to form a redistribution structure on a bridge element, and then bond multiple chips to the redistribution structure in a flip-chip manner. Therefore, the bridge element overlapping with the adjacent chips can shorten the signal transmission path between the adjacent chips. In order to protect the chips and the bridge element, a conventional method is to adopt a molding compound to cover the bridge element and the chips. However, even if the chips are correctly positioned, the injection of the molding compound may still cause alignment shift of the chips. and the thermal curing process of the molding compound may accumulate stress on the contact surface between the chips and the material due to the large difference in thermal expansion coefficient.

### SUMMARY

The disclosure provides a manufacturing method of an electronic package, which is used to manufacture the electronic package.

The disclosure provides an electronic package, which is used to provide preferable packaging quality.

A manufacturing method of an electronic package according to an embodiment of the disclosure includes the following steps. Multiple chips and a base dielectric layer are provided. A back surface of each of the chips is fixed to a back surface temporary carrier via a back surface temporary bonding layer. The base dielectric layer surrounds each of the chips and covers the back surface temporary bonding layer. A material of the base dielectric layer includes a silicate composite material or a material suitable for chemical-mechanical polishing. At least one bridge element is installed on active surfaces of the adjacent chips such that the bridge element respectively partially overlaps with the adjacent chips. Multiple bridging pads of the bridge element are respectively bonded to multiple first chip pads of the active surfaces of the adjacent chips. An intermediate dielectric layer covering the base dielectric layer, the chips, and the bridge element is formed. The bridge element and the intermediate dielectric layer are thinned and planarized. Multiple intermediate conductive vias and a redistribution structure are formed. The intermediate conductive vias respectively pass through the intermediate dielectric layer and are respectively connected to multiple second chip pads of the active surfaces of the chips, and the redistribution structure is on the intermediate dielectric layer and the intermediate conductive vias. Multiple conductive bumps are formed on the redistribution structure. The back surface temporary bonding layer and the back surface temporary carrier are removed to expose the back surface of each of the chips.

An electronic package according to an embodiment of the disclosure includes a sub-package. The sub-package includes multiple chips, a base dielectric layer, at least one bridge element, an intermediate dielectric layer, multiple intermediate conductive vias, a redistribution structure, and multiple conductive bumps. The base dielectric layer covers the chips and exposes active surfaces and back surfaces of at least part of the chips. A material of the base dielectric layer includes a silicate composite material or a material suitable for chemical-mechanical polishing. The at least one bridge element respectively partially overlaps with the adjacent chips. Multiple bridging pads of the bridge element are respectively bonded to multiple first chip pads of the active surfaces of the adjacent chips. The intermediate dielectric layer is disposed on the chips and the base dielectric layer and surrounds the at least one bridge element. The intermediate conductive vias pass through the intermediate dielectric layer and are respectively connected to multiple second chip pads of the active surfaces of the chips. The redistribution structure is disposed on the intermediate dielectric layer and the intermediate conductive vias. The conductive bumps are disposed on the redistribution structure.

Based on the above, the material of the base dielectric layer and the material of the intermediate dielectric layer can reduce the interface stress between the material and each chip, so that the control of the material and processing is easier to obtain a finished product with high reliability. Moreover, the direct copper bond of the bridge element to the chips also helps to drastically improve transmission performance and power cost performance ratio. In other words, the bridging pads of the bridge element are respectively bonded to the first chip pads of the active surfaces of the adjacent chips, which helps to reduce circuit power, increase bridging density, and achieve high-performance computing applications.

### BRIEF DESCRIPTION OF THE DRAWINGS

FIG. 1A to FIG. 1L illustrate a manufacturing method of an electronic package according to an embodiment of the disclosure.

FIG. 2 illustrates an electronic package according to an embodiment of the disclosure.

FIG. 3A to FIG. 3J illustrate a manufacturing method of an electronic package according to another embodiment of the disclosure.

FIG. 4 illustrates an electronic package according to another embodiment of the disclosure.

### DESCRIPTION OF THE EMBODIMENTS

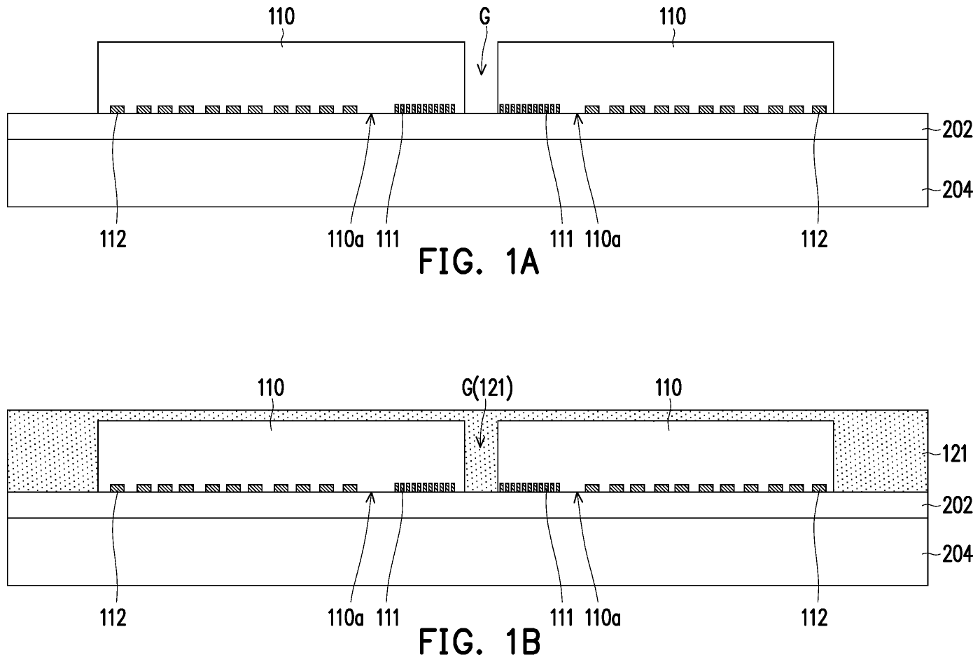

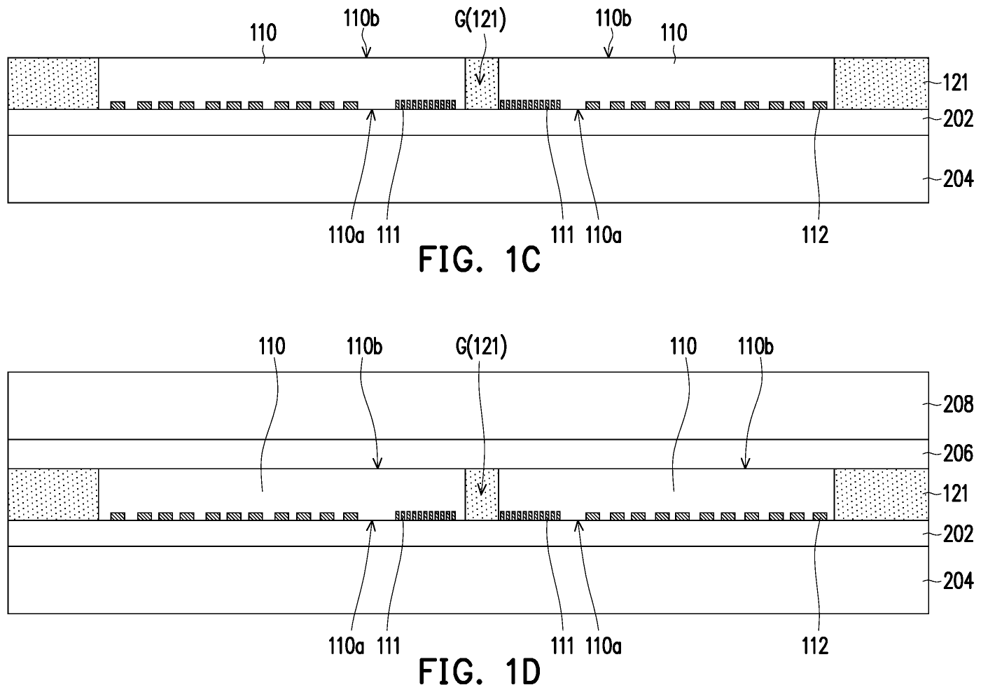

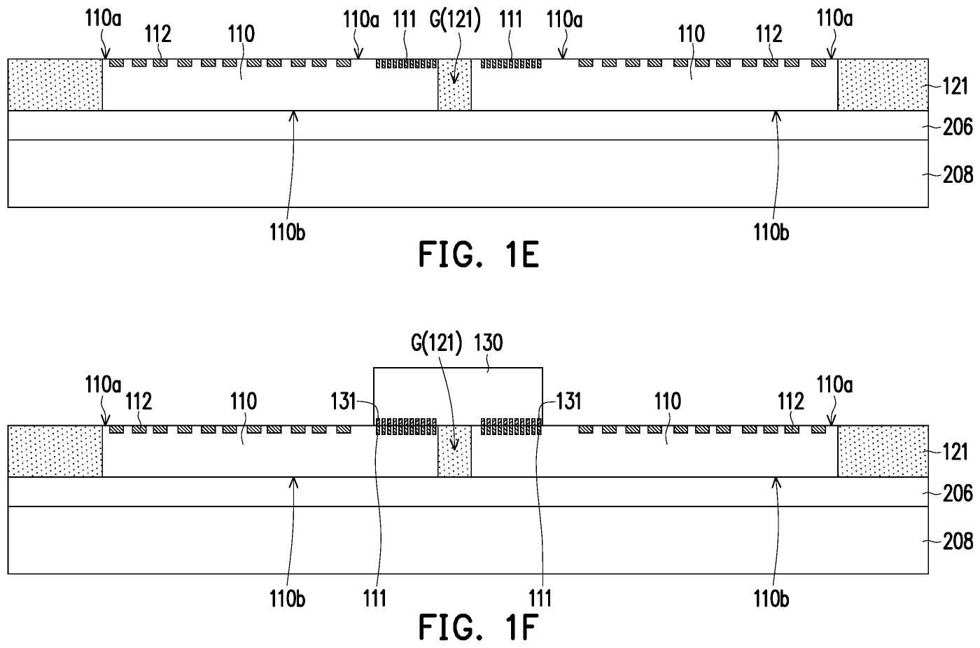

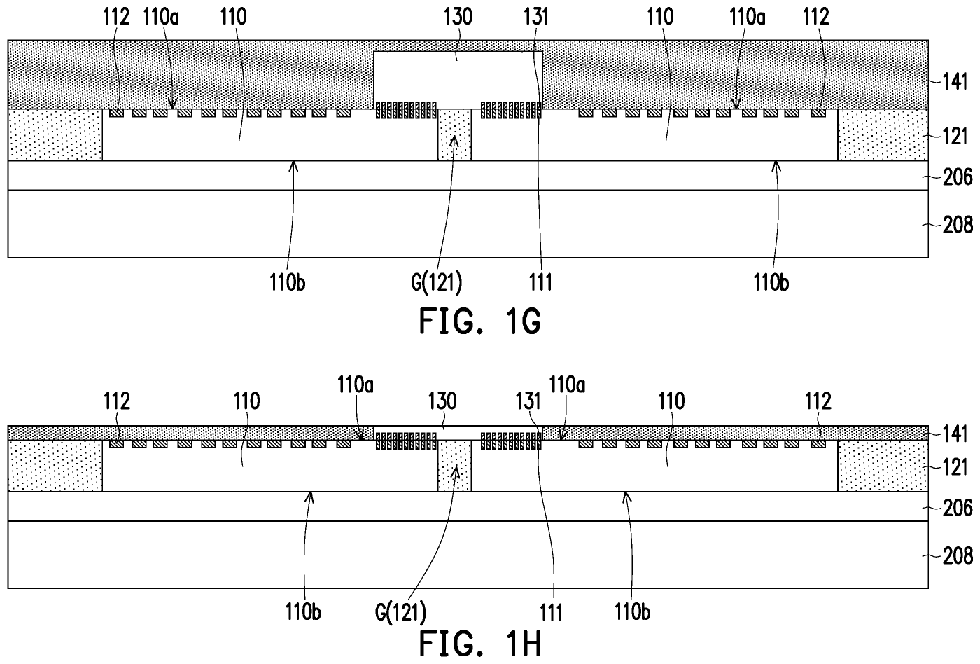

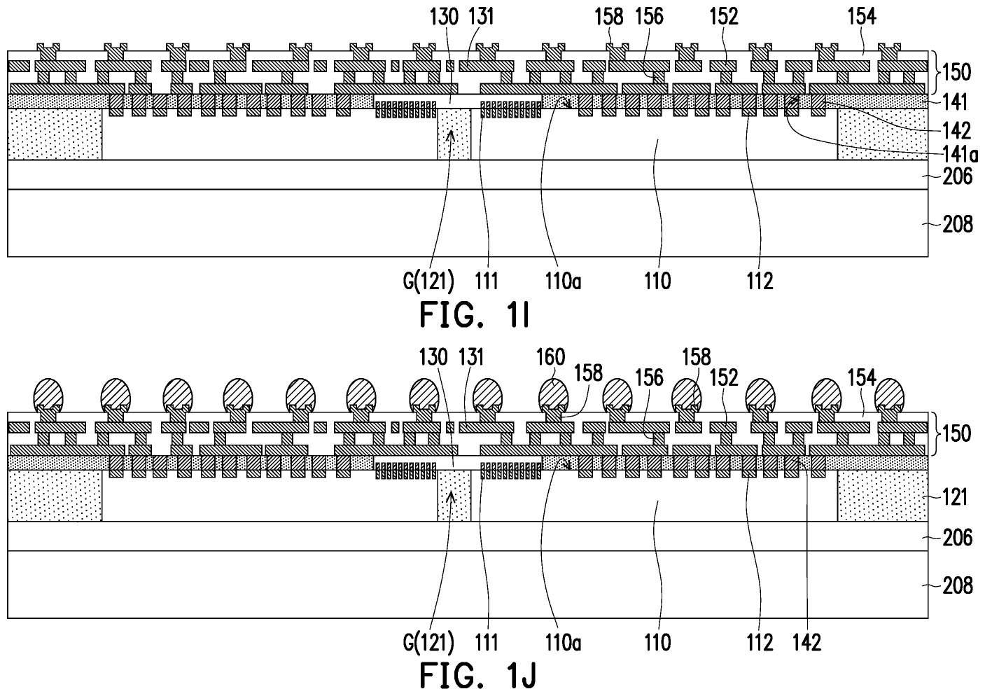

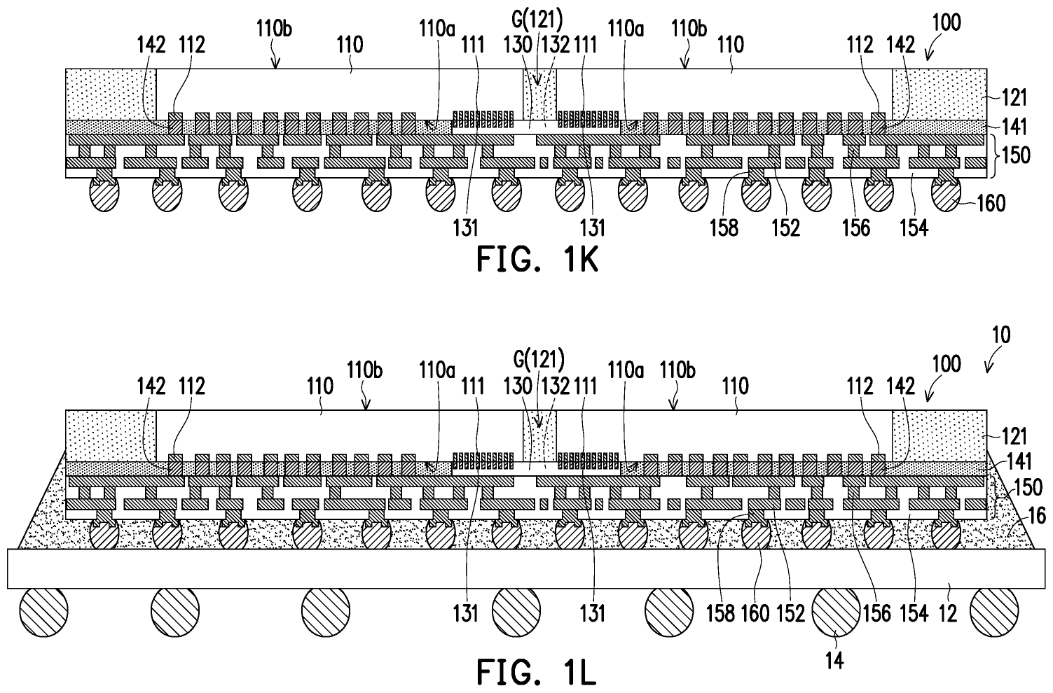

A manufacturing method of an electronic package according to an embodiment of the disclosure will be described below with reference to FIG. 1A to FIG. 1L.

Please refer to FIG. 1A. Multiple chips 110 are fixed to a front surface temporary carrier 204 via a front surface temporary bonding layer 202. An active surface 110a of each of the chips 110 faces the front surface temporary bonding layer 202. In the embodiment, the front surface temporary bonding layer 202 may be a release film.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that an electronic package 10 may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip, and may also be a combination of two chips with the same function.

Please refer to FIG. 1B. A base dielectric layer 121 covering the chips 110 and the front surface temporary bonding layer 202 is formed, and the base dielectric layer 121 fills a gap G between two adjacent chips 110. The material of the base dielectric layer 121 includes a silicate composite material or a material suitable for chemical-mechanical polishing (CMP). The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to t be used as the material for chemical-mechanical polishing due to particle issues, so the polymer material (the molding compound) cannot be used as the material of the base dielectric layer 121 in the disclosure. In addition, the materials have a relatively low coefficient of thermal expansion (CTE). The coefficient of thermal expansion is, for example, less than 10 ppm/° C., and may be more preferably controlled to be less than 5 ppm/° C. Therefore, the coefficient of thermal expansion of the base dielectric layer 121 is similar to the coefficient of thermal expansion of silicon. In other words, the coefficient of thermal expansion of the base dielectric layer 121 is similar to the coefficient of thermal expansion of the chip 110, so that chip warpage caused by the large difference between the coefficients of thermal expansion of the chip 110 and the base dielectric layer 121 in the past can be prevented. In the embodiment, the base dielectric layer 121 may be formed by spray coating, spin coating, or deposition.

It is worth mentioning that in the known packaging technology, the molding compound is often used to cover the chip, but the coefficient of thermal expansion of the molding compound is much greater than the coefficient of thermal expansion of the chip. Moreover, the particles of the molding compounds are larger, so it is not easy for the particles to fill the gap, and the molding compound is also prone to stress. However, the disclosure uses a nanoscale material with a coefficient of thermal expansion close to the coefficient of thermal expansion of silicon. The material has smaller particles and improved filling capability, so the material can effectively fill the gap. In the embodiment, the base dielectric layer 121 may fill the gap G between two adjacent chips 110.

Please refer to FIG. 1C. The chips 110 and the base dielectric layer 121 are thinned and planarized to expose a back surface 110b of each of the chips 110. In the embodiment, chemical-mechanical polishing may be adopted for thinning and planarization. Through this step, the issue that the thicknesses of the chips 110 on the front surface temporary bonding layer 202 are different in some cases can be solved. Therefore, after the step of thinning and planarization, the back surfaces 110b of the chips 110 and the base dielectric layer 121 may form a coplanar surface. In an embodiment, the thickness of the chips 110 after thinning is less than the thickness of the chips 110 before thinning.

Please refer to FIG. 1D. The thinned and planarized chips 110 and base dielectric layer 121 are fixed to a back surface temporary carrier 208 via a back surface temporary bonding layer 206. In the embodiment, the back surface temporary bonding layer 206 may be a release film.

Please refer to FIG. 1E. The front surface temporary bonding layer 202 and the front surface temporary carrier 204 are removed to expose the active surface 110a of each of the chips 110, and the active surface 110a is subjected to chemical-mechanical polishing and surface treatment and activation.

In the embodiment, the chips 110 and the base dielectric layer 121 may be provided by the above steps corresponding to FIG. 1A to FIG. 1E.

Please refer to FIG. 1F. At least one bridge element 130 is installed on the active surfaces 110a of the adjacent chips 110 such that the bridge element 130 respectively partially overlaps with the adjacent chips 110. Multiple bridging pads 131 of the bridge element 130 may be respectively bonded to multiple first chip pads 111 of the active surfaces 110a of the adjacent chips 110. In other words, an active surface of the bridge element 130 and a part of the active surface 110a of each of the chips 110 are in contact with each other. Therefore, the adjacent chips 110 may be directly electrically connected to each other via the bridge element 130 to shorten a signal transmission path between the chips 110. In addition, in the embodiment, although one bridge element being connected to two chips is used as an example, the disclosure is not limited thereto. In some embodiments, there may be more than two chips, and the bridge element is not limited to one, which may be determined depending on requirements.

In an embodiment, the material of the bridge element 130 may include an inorganic material such as silicon, glass, and ceramics or an organic material. The bridge element 130 may be an active element or a passive element. Furthermore, in the embodiment, the connection between the bridge element 130 and the chip 110 is a direct connection (pad to pad) between the bridging pad 131 and the first chip pad 111. Compared with the prior art, each chip is connected to the bridge element through a redistribution structure (redistribution layer, RDL). The embodiment may further shorten a transmission distance of electrical signals between the chips, and there is less issue of alignment shift. Furthermore, in an embodiment, the size of the first chip pad 111 is not greater than the size of a second chip pad 112. A pitch of two adjacent first chip pads 111 is not greater than a pitch of two adjacent second chip pads 112, and the pitch of two adjacent first chip pads 111 is, for example, less than 10 μm. In addition, a distribution density of the first chip pads 111 may be greater than a distribution density of the second chip pads 112.

Please refer to FIG. 1G. An intermediate dielectric layer 141 covering the base dielectric layer 121, the chips 110, and the bridge element 130 is formed. The material of the intermediate dielectric layer 141 includes a silicate composite material, silicon oxide, derivatives of silicon oxide, silicon oxynitride, silicon carbonitride, polyimide (PI), or benzocyclobutene (BCB). In an embodiment, the silicate composite material is preferably a silicate nanocomposite material. In an embodiment, the materials of the intermediate dielectric layer 141 and the base dielectric layer 121 may be the same or different and may be determined depending on the requirements of different situations. In addition, the material of the intermediate dielectric layer 141 includes a material suitable for chemical-mechanical polishing, and is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the intermediate dielectric layer 141. In addition, in an embodiment, the intermediate dielectric layer 141 does not fill the gap between two adjacent bridging pads 131, nor does the intermediate dielectric layer 141 fill the gap between two adjacent first chip pads 111.

Please refer to FIG. 1H. The bridge element 130 and the intermediate dielectric layer 141 are thinned and planarized. In the embodiment, chemical-mechanical polishing may be adopted for thinning and planarization. In addition, through the step of thinning and planarizing the bridge element 130 and the intermediate dielectric layer 141, the overall thickness of the electronic package may be reduced, so that the thinned electronic package may be applied in lighter and thinner products. In addition, after the step of thinning and planarization, a back surface of the bridge element 130 and the intermediate dielectric layer 141 may form a coplanar surface. In an embodiment, the thickness of the thinned bridge element 130 is less than the thickness of the chips 110.

Please refer to FIG. 1I. Multiple intermediate conductive vias 142 and a redistribution structure 150 are formed. The intermediate conductive vias 142 respectively pass through the intermediate dielectric layer 141 and are respectively connected to the second chip pads 112 of the active surfaces 110a of the chips 110. The redistribution structure 150 is on the intermediate dielectric layer 141 and the intermediate conductive vias 142. In the embodiment, the chip 110 is electrically connected to the intermediate conductive vias 142 and the redistribution structure 150 by using the second chip pads 112, and the chip 110 is electrically connected to the bridge element 130 by using the first chip pads 111 and the bridging pads 131.

In the embodiment, forming the intermediate conductive vias 142 may include forming multiple through holes in the intermediate dielectric layer 141, and filling a conductive material into the through holes to form the intermediate conductive vias 142.

In the embodiment, the redistribution structure 150 may be formed by adopting a build-up process. The redistribution structure 150 may include multiple redistribution patterned conductive layers 152, multiple redistribution dielectric layers 154, and multiple redistribution conductive vias 156. The redistribution patterned conductive layers 152 are alternately stacked with the redistribution dielectric layers 154. The redistribution conductive vias 156 are respectively connected to the redistribution patterned conductive layers 152. In addition, multiple under bump metallurgy (UBM) layers 158 are further formed on multiple parts of the redistribution patterned conductive layers 152 farthest from the chips 110.

Please refer to FIG. 1J. Multiple conductive bumps 160 are formed on the redistribution structure 150. In the embodiment, the conductive bumps 160 may be respectively formed on the under bump metallurgy layers 158 of the redistribution structure 150.

Please refer to FIG. 1K. The back surface temporary bonding layer 206 and the back surface temporary carrier 208 are removed to expose the back surface 110b of each of the chips 110. So far, a sub-package 100 is completed.

Please refer to FIG. 1L. The conductive bumps 160 are connected to a circuit carrier 12. and multiple conductive balls 14 are connected to the circuit carrier 12. In the embodiment, after the conductive bumps 160 are connected to the circuit carrier 12, an underfill 16 may be filled between the sub-package 100 and the circuit carrier 12 and covers the conductive bumps 160. So far, the electronic package 10 is completed.

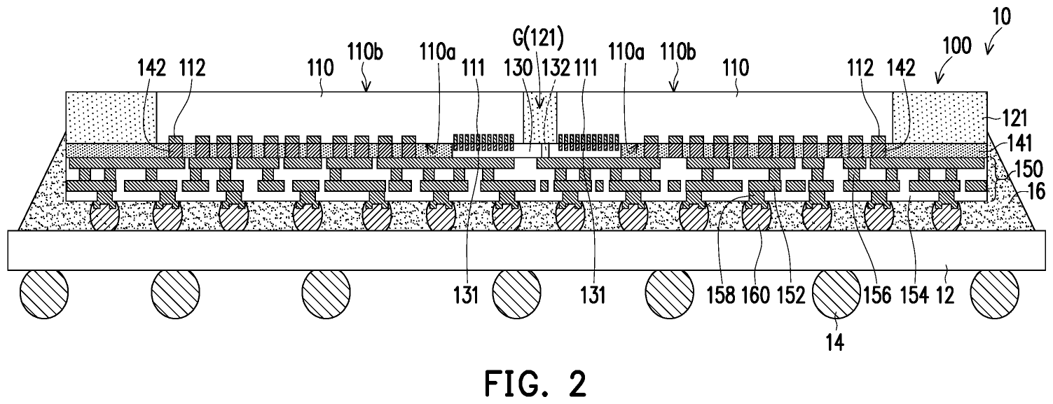

An electronic package according to an embodiment of the disclosure will be described below with reference to FIG. 2 and may be produced by the manufacturing method of the above embodiment or other manufacturing methods.

Please refer to FIG. 2. In the embodiment, the electronic package 10 includes the sub-package 100. The sub-package 100 includes the chips 110, the base dielectric layer 121, the at least one bridge element 130, the intermediate dielectric layer 141, the intermediate conductive vias 142, the redistribution structure 150, and the conductive bumps 160. The base dielectric layer 121 covers the chips 110 and exposes all active surfaces 110a and back surfaces 110b of the chips 110, and the base dielectric layer 121 fills the gap G between two adjacent chips 110. The material of the base dielectric layer 121 includes a silicate composite material or a material suitable for chemical-mechanical polishing. The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 121.

The bridge element 130 respectively partially overlaps with the adjacent chips 110. wherein the thickness of the bridge element 130 is less than the thickness of the chips 110. The bridging pads 131 of the bridge element 130 may be respectively bonded to the first chip pads 111 of the active surfaces 110a of the adjacent chips 110. The intermediate dielectric layer 141 is disposed on the chips 110 and the base dielectric layer 121 and surrounds the bridge element 130.

The material of the intermediate dielectric layer 141 is a silicate composite material, silicon oxide, derivatives of silicon oxide, silicon oxynitride, silicon carbonitride, polyimide, or benzocyclobutene. The silicate composite material is preferably a silicate nanocomposite material. In an embodiment, the materials of the intermediate dielectric layer 141 and the base dielectric layer 121 may be the same or different and may be determined depending on the requirements of different situations. In addition, the material of the intermediate dielectric layer 141 includes a material suitable for chemical-mechanical polishing, and is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the intermediate dielectric layer 141.

The intermediate conductive vias 142 pass through the intermediate dielectric layer 141 and are respectively connected to the second chip pads 112 of the active surfaces 110a of the chips 110. The redistribution structure 150 is disposed on the intermediate dielectric layer 141 and the intermediate conductive vias 142. The conductive bumps 160 are disposed on the redistribution structure 150.

In the embodiment, the base dielectric layer 121 may fill the gap G between two adjacent chips 110. In addition, the base dielectric layer 121 has a material with a low coefficient of thermal expansion. The coefficient of thermal expansion is, for example, less than 10 ppm/° C., and may be more preferably controlled to be less than 5 ppm/° C. Therefore, the coefficient of thermal expansion of the base dielectric layer 121 is similar to the coefficient of thermal expansion of silicon. In other words, the coefficient of thermal expansion of the base dielectric layer 121 is similar to the coefficient of thermal expansion of the chip 110, so that chip warpage caused by the large difference between the coefficient of thermal expansion of the chip 110 and the base dielectric layer 121 in the past can be prevented.

In the embodiment, the distribution density of the first chip pads 111 may be greater than the distribution density of the second chip pads 112. In addition, since the bridging pads 131 of the bridge element 130 are directly bonded to the first chip pads 111 of the active surfaces 110a of the chips 110, the base dielectric layer 121 or the intermediate dielectric layer 141 does not fill the gap between two adjacent bridging pads 131, nor does the base dielectric layer 121 or the intermediate dielectric layer 141 fill the gap between two adjacent first chip pads 111.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package 10 may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip. In some embodiments, the chips may also be a combination of two chips with the same function.

In the embodiment, the bridge element 130 may be an active element or a passive element. The material of the bridge element 130 may include an inorganic material (for example, silicon. glass, ceramics) or an organic material. The bridge element 130 may have multiple bridge conductive vias 132, and the chips 110 are electrically connected to the redistribution structure 150 via the bridge conductive vias 132.

In the embodiment, the electronic package 10 may include the circuit carrier 12. The sub-package 100 is installed on the circuit carrier 12. In addition, the electronic package 10 may further include the conductive balls 14. The conductive balls 14 are connected to the circuit carrier 12. In addition, the electronic package 10 may further include the underfill 16. The underfill 16 is filled between the redistribution structure 150 and the circuit carrier 12 and covers the conductive bumps 160.

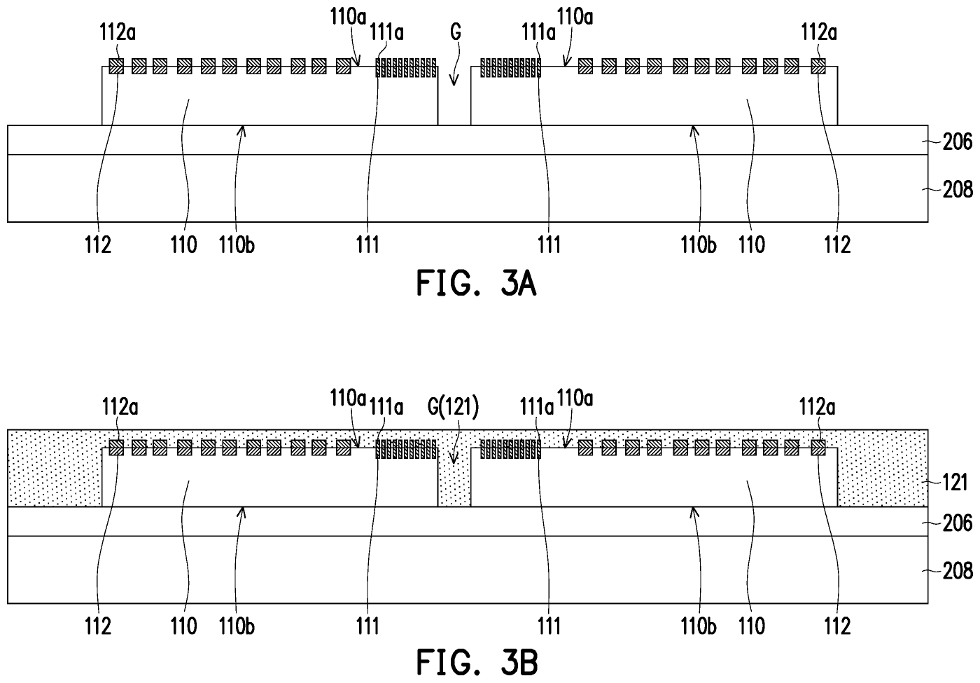

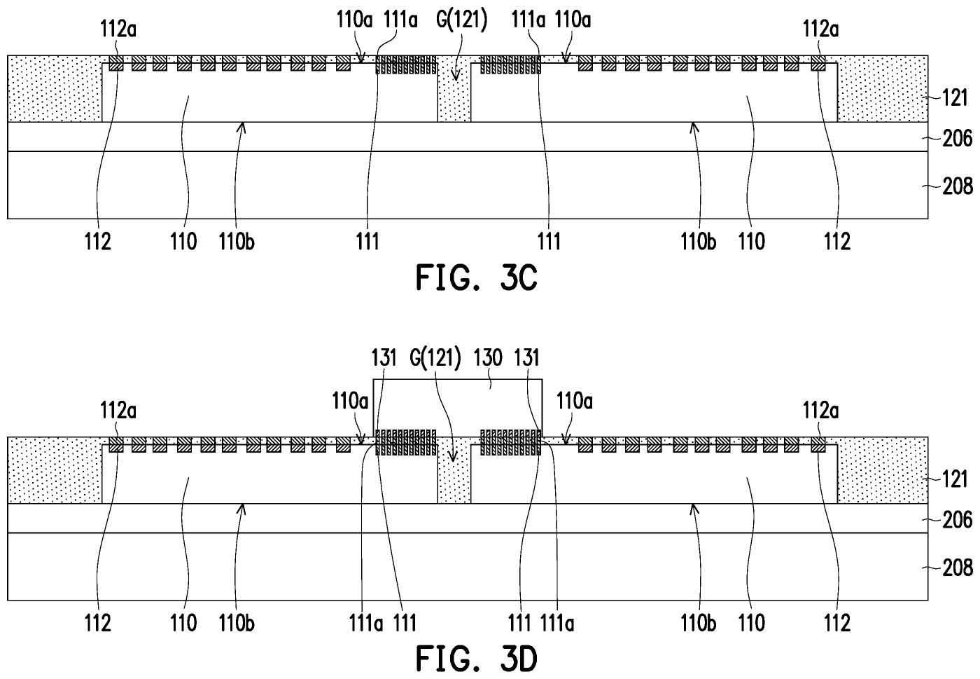

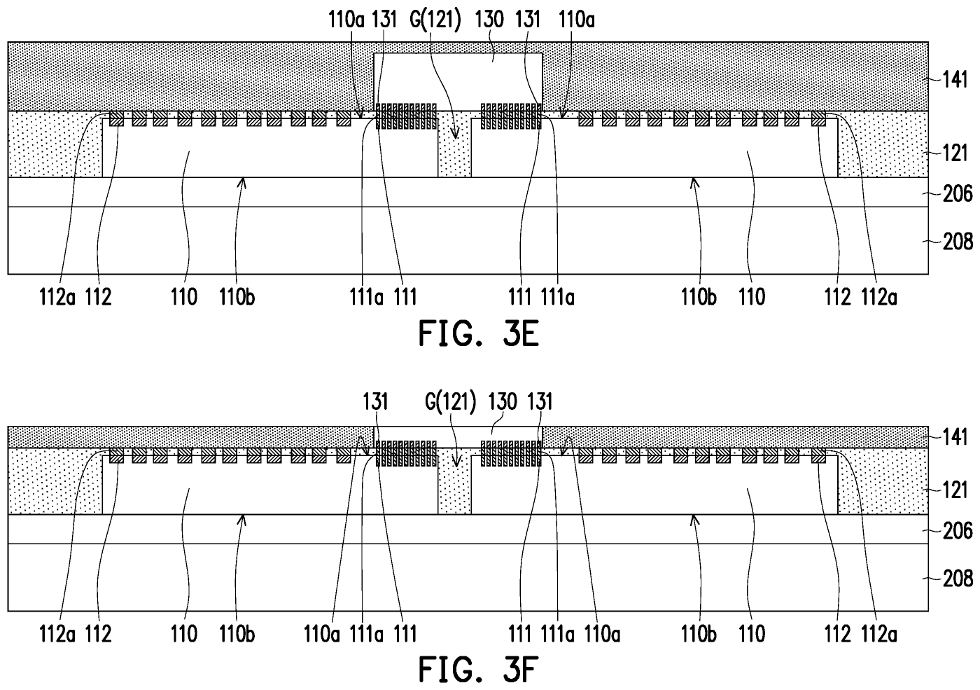

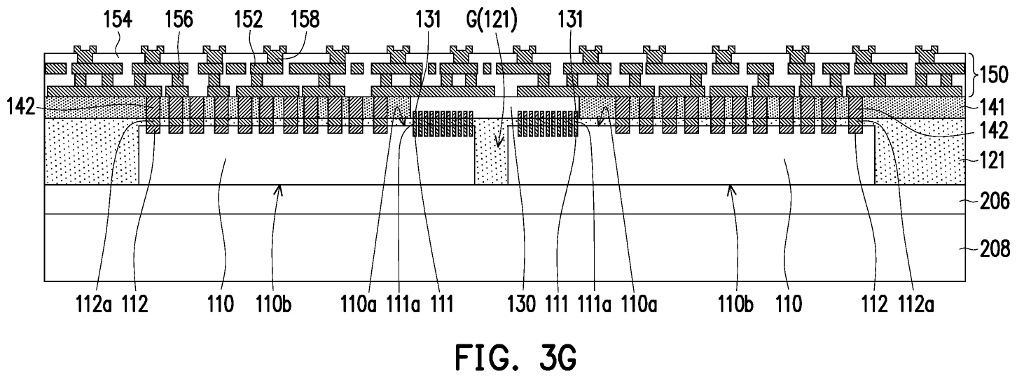

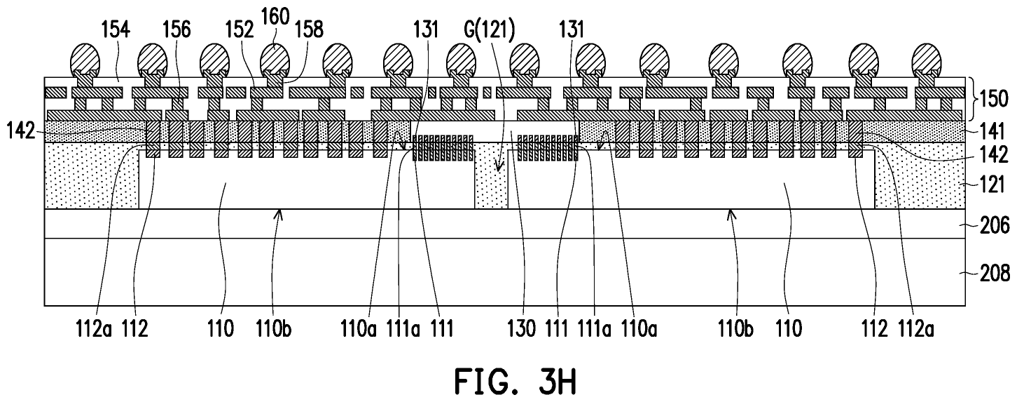

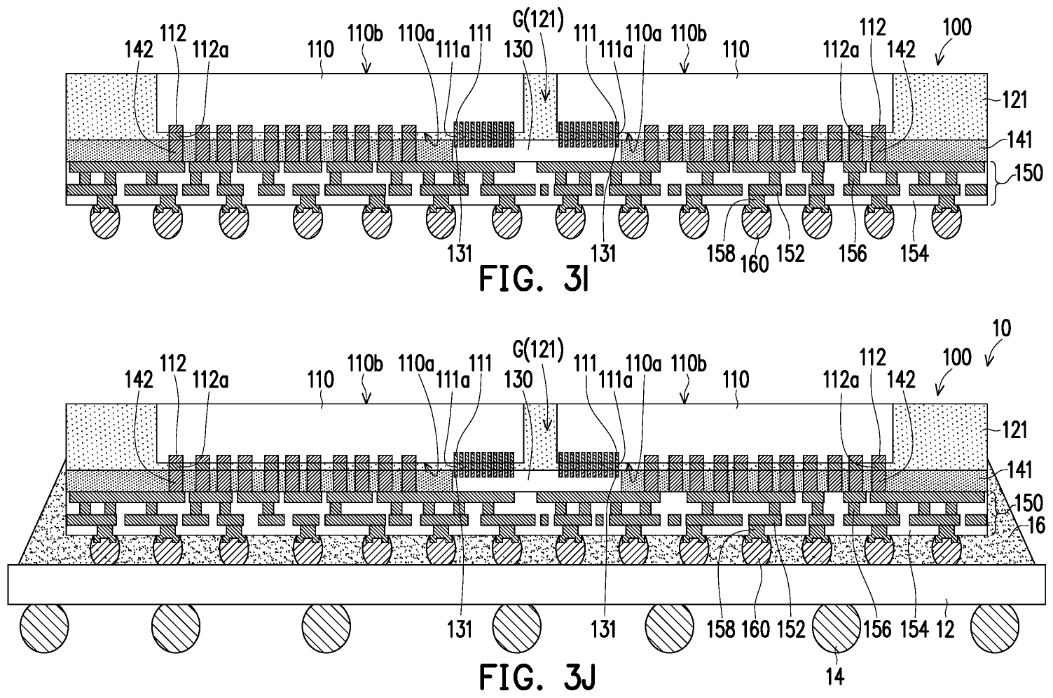

A manufacturing method of an electronic package according to another embodiment of the disclosure will be described below with reference to FIG. 3A to FIG. 3J.

Please refer to FIG. 3A. The chips 110 are fixed to the back surface temporary carrier 208 via the back surface temporary bonding layer 206. The back surface 110b of each of the chips 110 faces the back surface temporary bonding layer 206. Each of the chips 110 has multiple first pad pillars 111a and multiple second pad pillars 112a. The first pad pillars 111a are respectively located on the first chip pads 111 of the active surfaces 110a of the chips 110, and the second pad pillars 112a are respectively located on the second chip pads 112 of the active surfaces 110a of the chips 110. In the embodiment, the back surface temporary bonding layer 206 may be a release film.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package 10 may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip, and may also be a combination of two chips with the same function.

Please refer to FIG. 3B. The base dielectric layer 121 is formed. The base dielectric layer 121 covers the chips 110, the first pad pillars 111a, the second pad pillars 112a, and the back surface temporary bonding layer 206, and the base dielectric layer 121 fills the gap G between two adjacent chips 110. The material of the base dielectric layer 121 includes a silicate composite material or a material suitable for chemical-mechanical polishing. The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 131. In addition, the materials have a relatively low coefficient of thermal expansion. The coefficient of thermal expansion is, for example, less than 10 ppm/° C., and may be more preferably controlled to be less than 5 ppm/° C. Therefore, the coefficient of thermal expansion of the base dielectric layer 121 is similar to the coefficient of thermal expansion of silicon. In other words, the coefficient of thermal expansion of the base dielectric layer 121 is similar to the coefficient of thermal expansion of the chip 110, so that chip warpage caused by the large difference between the coefficient of thermal expansion of the chip 110 and the base dielectric layer 121 in the past can be prevented. In the embodiment, the base dielectric layer 121 may be formed by spray coating, spin coating, or deposition.

It is worth mentioning that in the known packaging technology, the molding compound is often used to cover the chip, but the coefficient of thermal expansion of the molding compound is much greater than the coefficient of thermal expansion of the chip. Moreover, particles are larger, so it is not easy for the particles to fill the gap, and the molding compound is also prone to stress. However, the disclosure uses a nanoscale material with a coefficient of thermal expansion close to the coefficient of thermal expansion of silicon. The material has smaller molecular particles and improved filling capability, so the material can effectively fill the gap. In the embodiment, the base dielectric layer 121 may fill the gap G between two adjacent chips 110.

Please refer to FIG. 3C. The base dielectric layer 121 is thinned and planarized to expose the first pad pillars 111a and the second pad pillars 112a. In the embodiment, chemical-mechanical polishing may be adopted for thinning and planarization. Through this step, a contact array of a contour plane may be formed via the first pad pillars 111a and the second pad pillars 112a, and the first pad pillars 111a and the second pad pillars 112a may also be subjected to surface treatment and activation.

In the embodiment, the chips 110 and the base dielectric layer 121 may be provided by the above steps corresponding to FIG. 3A to FIG. 3C.

Please refer to FIG. 3D. The at least one bridge element 130 is installed on the active surfaces 110a of the adjacent chips 110. In detail, the bridge element 130 is located on a part of the base dielectric layer 121 such that the bridge element 130 respectively partially overlaps with the adjacent chips 110 on a projection plane. The bridging pads 131 of the bridge element 130 may be respectively bonded to the first chip pads 111 via being respectively bonded to the first pad pillars 111a. In other words, the active surface of the bridge element 130 and a part of the active surface 110a of each of the chips 110 are in contact with each other through the first pad pillars 111a, instead of connecting the active surface of the bridge element 130 and a part of the active surface 110a of each of the chips 110 through a known redistribution structure. Therefore, the adjacent chips 110 may be electrically connected to each other via the bridge element 130 to shorten the signal transmission path between the chips 110. In addition, in the embodiment. although one bridge element being connected to two chips is used as an example, the disclosure is not limited thereto. In some embodiments, there may be more than two chips, and the bridge element is not limited to one, which may be determined depending on requirements.

In an embodiment, the material of the bridge element 130 may include an inorganic material such as silicon, glass, and ceramics or an organic material. The bridge element 130 may be an active element or a passive element. In addition, in the embodiment, the bridge element 130 is connected to the chips 110 through the first pad pillars 111a. Compared with the prior art, each chip is connected to the bridge element through a redistribution structure (redistribution layer, RDL). The embodiment may further shorten the transmission distance of electrical signals between the chips, and there is less issue of alignment shift. Furthermore, in an embodiment, the size of the first chip pad 111 is not greater than the size of the second chip pad 112. The pitch of two adjacent first chip pads 111 is not greater than the pitch of two adjacent second chip pads 112. and the pitch of two adjacent first chip pads 111 is, for example, less than 10 μm. In addition, the distribution density of the first chip pads 111 may be greater than the distribution density of the second chip pads 112.

Please refer to FIG. 3E. The intermediate dielectric layer 141 covering the base dielectric layer 121, the chips 110, and the bridge element 130 is formed. The material of the intermediate dielectric layer 141 includes a silicate composite material, silicon oxide, derivatives of silicon oxide, silicon oxynitride, silicon carbonitride, polyimide, or benzocyclobutene. In an embodiment, the silicate composite material is preferably a silicate nanocomposite material. In an embodiment, the materials of the intermediate dielectric layer 141 and the base dielectric layer 121 may be the same or different and may be determined depending on the requirements of different situations. In addition, the material of the intermediate dielectric layer 141 includes a material suitable for chemical-mechanical polishing, and is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the intermediate dielectric layer 141.

Please refer to FIG. 3F. The bridge element 130 and the intermediate dielectric layer 141 are thinned and planarized. In the embodiment, chemical-mechanical polishing may be adopted for thinning and planarization. In addition, through the step of thinning and planarizing the bridge element 130 and the intermediate dielectric layer 141, the overall thickness of the electronic package may be reduced, so that the thinned electronic package may be applied in lighter and thinner products. In addition, after the step of thinning and planarization, the back surface of the bridge element 130 and the intermediate dielectric layer 141 may form a coplanar surface. In an embodiment, the thickness of the thinned bridge element 130 is less than the thickness of the chips 110.

Please refer to FIG. 3G. The intermediate conductive vias 142 and the redistribution structure 150 are formed. The intermediate conductive vias 142 respectively pass through the intermediate dielectric layer 141 and may be connected to the corresponding second chip pads 112 via being respectively connected to the second pad pillars 112a. The redistribution structure 150 is on the intermediate dielectric layer 141 and the intermediate conductive vias 142. In the embodiment, the chip 110 is electrically connected to the intermediate conductive vias 142 and the redistribution structure 150 by using the second chip pads 112 and the second pad pillars 112a thereon, and the chip 110 is electrically connected to the bridge element 130 by using the first chip pads 111, the first pad pillars 111a, and the bridging pads 131.

In the embodiment, forming the intermediate conductive vias 142 may include forming multiple through holes in the intermediate dielectric layer 141, and filling a conductive material into the through holes to form the intermediate conductive vias 142.

In the embodiment, the redistribution structure 150 may be formed by adopting a build-up process. The redistribution structure 150 may include the redistribution patterned conductive layers 152, the redistribution dielectric layers 154, and the redistribution conductive vias 156. The redistribution patterned conductive layers 152 are alternately stacked with the redistribution dielectric layers 154. The redistribution conductive vias 156 are respectively connected to the redistribution patterned conductive layers 152. In addition, the under bump metallurgy layers 158 are further formed on the parts of the redistribution patterned conductive layer 152 farthest from the chips 110.

Please refer to FIG. 3H. The conductive bumps 160 are formed on the redistribution structure 150. In the embodiment, the conductive bumps 160 may be respectively formed on the under bump metallurgy layer 158 of the redistribution structure 150.

Please refer to FIG. 3I. The back surface temporary bonding layer 206 and the back surface temporary carrier 208 are removed to expose the back surface 110b of each of the chips 110. So far, the sub-package 100 is completed.

Please refer to FIG. 3J. The conductive bumps 160 are connected to the circuit carrier 12, and the conductive balls 14 are connected to the circuit carrier 12. In the embodiment, after the conductive bumps 160 are connected to the circuit carrier 12, the underfill 16 may be filled between the sub-package 100 and the circuit carrier 12 and covers the conductive bumps 160. So far, the electronic package 10 is completed.

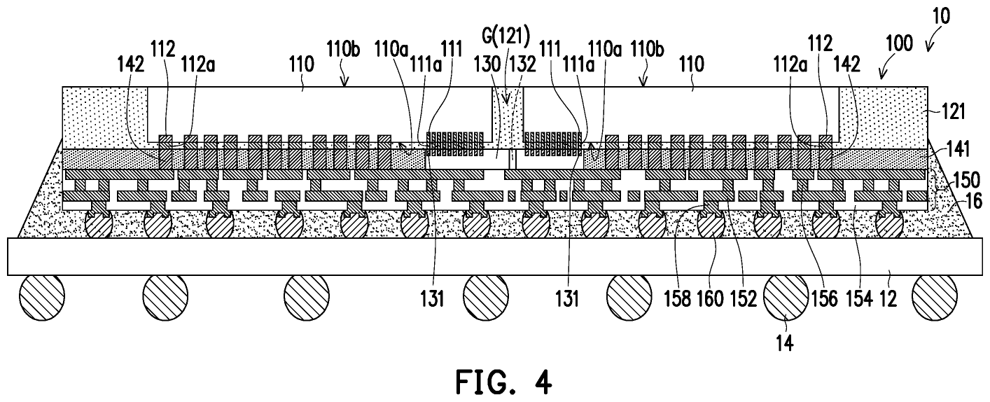

An electronic package according to another embodiment of the disclosure will be described below with reference to FIG. 4 and may be produced by the manufacturing method of the above embodiment or other manufacturing methods.

Please refer to FIG. 4. In the embodiment, the electronic package 10 includes the sub-package 100. The sub-package 100 includes the chips 110, the base dielectric layer 121, the at least one bridge element 130, the intermediate dielectric layer 141, the intermediate conductive vias 142, the redistribution structure 150, and the conductive bumps 160. The base dielectric layer 121 covers the chips 110 and exposes a part of the active surfaces 110a and the back surfaces 110b of the chips 110, and the base dielectric layer 121 fills the gap G between two adjacent chips 110.

The material of the base dielectric layer 121 includes a silicate composite material or a material suitable for chemical-mechanical polishing. The silicate composite material is preferably a silicate nanocomposite material. The material suitable for chemical-mechanical polishing is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the base dielectric layer 121.

The bridge element 130 partially overlaps with the chips 110 on a projection plane. The bridging pads 131 of the bridge element 130 may be respectively bonded to the first chip pads 111 of the active surfaces 110a of the adjacent chips 110. Specifically, each of the chips 110 has the first pad pillars 111a. The first pad pillars 111a are respectively located on the first chip pads 111 and are surrounded by the base dielectric layer 121. The bridging pads 131 are bonded to the corresponding first chip pads 111 via being respectively bonded to the first pad pillars 111a.

The intermediate dielectric layer 141 is disposed on the chips 110 and the base dielectric layer 121 and surrounds the bridge element 130. The material of the intermediate dielectric layer 141 is a silicate composite material, silicon oxide, derivatives of silicon oxide, silicon oxynitride, silicon carbonitride, polyimide, or benzocyclobutene. The silicate composite material is preferably a silicate nanocomposite material. In an embodiment, the materials of the intermediate dielectric layer 141 and the base dielectric layer 121 may be the same or different and may be determined depending on the requirements of different situations. In addition, the material of the intermediate dielectric layer 141 includes a material suitable for chemical-mechanical polishing, and is preferably a composite material or an inorganic compound. It is worth mentioning that known molding compounds are usually polymer materials with filler particles, and are not suitable to be used as the material for chemical-mechanical polishing due to particle issues, so the polymer material (the molding compound) cannot be used as the material of the intermediate dielectric layer 141.

The intermediate conductive vias 142 pass through the intermediate dielectric layer 141 and are respectively connected to the second chip pads 112 of the active surfaces 110a of the chips 110. Specifically, each of the chips 110 has the second pad pillars 112a. The second pad pillars 112a are respectively located on the second chip pads 112 and are surrounded by the base dielectric layer 121. The intermediate conductive vias 142 are bonded to the corresponding second chip pads 112 via being respectively bonded to the second pad pillars 112a. The redistribution structure 150 is disposed on the intermediate dielectric layer 141 and the intermediate conductive vias 142. The conductive bumps 160 are disposed on the redistribution structure 150.

In the embodiment, the base dielectric layer 121 may fill the gap G between two adjacent chips 110. In addition, the base dielectric layer 121 has a material with a low coefficient of thermal expansion. The coefficient of thermal expansion is, for example, less than 10 ppm/° C., and may be more preferably controlled to be less than 5 ppm/° C. Therefore, the coefficient of thermal expansion of the base dielectric layer 121 is similar to the coefficient of thermal expansion of silicon. In other words, the coefficient of thermal expansion of the base dielectric layer 121 is similar to the coefficient of thermal expansion of the chip 110, so that chip warpage caused by the large difference between the coefficient of thermal expansion of the chip 110 and the base dielectric layer 121 in the past can be prevented.

In the embodiment, the distribution density of the first chip pads 111 may be greater than the distribution density of the second chip pads 112.

In the embodiment, one of the chips 110 may be a central processing unit chip, a logic chip, a graphics processing chip, an input/output chip, a memory chip, a base band chip, a radio frequency (RF) chip, or an integrated circuit chip with a specific function. In other words, the chips 110 may include a combination of the chips of different functional types, so that the electronic package 10 may be used in a chiplet packaging technology, which is similar to system in package (SiP). Since the chips 110 may have different functions, the sizes of the chips 110 may be different. In some embodiments, the chips may be a combination of a central processing unit chip and a logic chip, a combination of a central processing unit chip and an input/output chip, a combination of a graphics processing chip and a memory chip, or a combination of a radio frequency chip and a base band chip. In some embodiments, the chips may also be a combination of two chips with the same function.

In the embodiment, the bridge element 130 may be an active element or a passive element. The material of the bridge element 130 may include an inorganic material (for example, silicon, glass, ceramics) or an organic material. The bridge element 130 may have the bridge conductive vias 132, and the chips 110 are electrically connected to the redistribution structure 150 via the bridge conductive vias 132. In addition, the thickness of the bridge element 130 is less than the thickness of the chips 110.

In the embodiment, the electronic package 10 may include the circuit carrier 12. The sub-package 100 is installed on the circuit carrier 12. In addition, the electronic package 10 may further include the conductive balls 14. The conductive balls 14 are connected to the circuit carrier 12. In addition, the electronic package 10 may further include the underfill 16. The underfill 16 is filled between the redistribution structure 150 and the circuit carrier 12 and covers the conductive bumps 160.

In summary, in the above embodiments, the materials of the base dielectric layer and the intermediate dielectric layer can reduce the interface stress between the material and each chip, especially at the junction of the horizontal and vertical planes of the chip, so that the control of the material and processing is easier to obtain a finished product with high reliability, and direct copper bond also helps to drastically improve transmission performance and power cost performance ratio. The bridging pads of the bridge element are respectively bonded to the first chip pads of the active surfaces of the adjacent chips, which helps to reduce circuit power, increase bridging density, and achieve high-performance computing applications. Under the selected material of the base dielectric layer, when the base dielectric layer is formed by spray coating, spin coating, or deposition, the gap between adjacent chips may be easily filled at low temperature, and the formation of the base dielectric layer is less likely to cause deflection of the chips to maintain alignment precision.

What is claimed is:

1. A manufacturing method of an electronic package, comprising:
providing a plurality of chips and a base dielectric layer, wherein a back surface of each of the chips is fixed to a back surface temporary carrier via a back surface temporary bonding layer. the base dielectric layer surrounds each of the chips and covers the back surface temporary bonding layer, and the base dielectric layer fills a gap between adjacent two of the chips, wherein a material of the base dielectric layer comprises a silicate composite material or a composite material suitable for chemical-mechanical polishing;
installing at least one bridge element on active surfaces of the adjacent chips such that the bridge element respectively partially overlaps with the adjacent chips, wherein a plurality of bridging pads of the bridge element are respectively bonded to a plurality of first chip pads of the active surfaces of the adjacent chips;
forming an intermediate dielectric layer covering the base dielectric layer, the chips, and the bridge element;
thinning and planarizing the bridge element and the intermediate dielectric layer;
forming a plurality of intermediate conductive vias and a redistribution structure, wherein the intermediate conductive vias respectively pass through the intermediate dielectric layer and are respectively connected to a plurality of second chip pads of the active surfaces of the chips, and the redistribution structure is on the intermediate dielectric layer and the intermediate conductive vias;
forming a plurality of conductive bumps on the redistribution structure; and
removing the back surface temporary bonding layer and the back surface temporary carrier to expose the back surface of each of the chips.

2. The manufacturing method of the electronic package according to claim 1, wherein in the step of thinning and planarizing the bridge element and the intermediate dielectric layer, a thickness of the planarized bridge element is less than a thickness of the chips.

3. The manufacturing method of the electronic package according to claim 1, wherein the base dielectric layer comprises a silicate nanocomposite material.

4. The manufacturing method of the electronic package according to claim 1, wherein the base dielectric layer comprises a composite material or an inorganic compound suitable for chemical-mechanical polishing.

5. The manufacturing method of the electronic package according to claim 1, wherein the bridge element has a plurality of bridge conductive vias, and the chips are electrically connected to the redistribution structure via the bridge conductive vias.

6. The manufacturing method of the electronic package according to claim 1, wherein a material of the intermediate dielectric layer comprises a silicate composite material, silicon oxide. derivatives of silicon oxide, silicon oxynitride, silicon carbonitride, polyimide, or benzocyclobutene.

7. The manufacturing method of the electronic package according to claim 1, further comprising:
connecting the conductive bumps to a circuit carrier; and
connecting a plurality of conductive balls to the circuit carrier.

8. The manufacturing method of the electronic package according to claim 1, wherein the step of providing the chips and the base dielectric layer comprises:
fixing the chips to a front surface temporary carrier via a front surface temporary bonding layer, wherein the active surface of each of the chips faces the front surface temporary bonding layer;
forming the base dielectric layer covering the chips and the front surface temporary bonding layer, wherein the base dielectric layer fills the gap between adjacent two of the chips;
thinning and planarizing the chips and the base dielectric layer to expose the back surface of each of the chips;
fixing the thinned and planarized chips and base dielectric layer to the back surface temporary carrier via the back surface temporary bonding layer; and
removing the front surface temporary bonding layer and the front surface temporary carrier to expose the active surface of each of the chips.

9. The manufacturing method of the electronic package according to claim 8, wherein after removing the front surface temporary bonding layer and the front surface temporary carrier to expose the active surface of each of the chips, the active surfaces are subjected to chemical-mechanical polishing and surface treatment and activation.

10. The manufacturing method of the electronic package according to claim 8, wherein the bridging pads are respectively directly bonded to the first chip pads.

11. The manufacturing method of the electronic package according to claim 8, wherein the base dielectric layer does not fill a gap between adjacent two of the bridging pads, and the base dielectric layer does not fill a gap between adjacent two of the first chip pads.

12. The manufacturing method of the electronic package according to claim 1, wherein the step of providing the chips and the base dielectric layer comprises:
fixing the chips to the back surface temporary carrier via the back surface temporary bonding layer, wherein the back surface of each of the chips faces the back surface temporary bonding layer, each of the chips has a plurality of first pad pillars and a plurality of second pad pillars, the first pad pillars are respectively located on the first chip pads, and the second pad pillars are respectively located on the second chip pads;
forming the base dielectric layer, wherein the base dielectric layer covers the chips, the first pad pillars, the second pad pillars, and the back surface temporary bonding layer, and the base dielectric layer fills the gap between adjacent two of the chips; and
thinning and planarizing the base dielectric layer to expose the first pad pillars and the second pad pillars.

13. The manufacturing method of the electronic package according to claim 12, wherein the bridging pads are respectively bonded to the first chip pads via being respectively bonded to the first pad pillars, and the intermediate conductive vias are respectively connected to the second chip pads via being respectively connected to the second pad pillars.

14. An electronic package, comprising:
a sub-package, comprising:
a plurality of chips;
a base dielectric layer, covering the chips and exposing active surfaces and back surfaces of at least part of the chips, wherein the base dielectric layer fills a gap between adjacent two of the chips, and a material of the base dielectric layer comprises a silicate composite material or a composite material suitable for chemical-mechanical polishing;
at least one bridge element, respectively partially overlapping with the adjacent chips. wherein a plurality of bridging pads of the bridge element are respectively bonded to a plurality of first chip pads of the active surfaces of the adjacent chips;
an intermediate dielectric layer, disposed on the chips and the base dielectric layer and surrounding the bridge element;
a plurality of intermediate conductive vias, passing through the intermediate dielectric layer and respectively connected to a plurality of second chip pads of the active surfaces of the chips;
a redistribution structure, disposed on the intermediate dielectric layer and the intermediate conductive vias; and
a plurality of conductive bumps, disposed on the redistribution structure.

15. The electronic package according to claim 14, wherein a thickness of the bridge element is less than a thickness of the chips.

16. The electronic package according to claim 14, wherein the base dielectric layer comprises a silicate nanocomposite material.

17. The electronic package according to claim 14, wherein the base dielectric layer comprises a composite material or an inorganic compound suitable for chemical-mechanical polishing.

18. The electronic package according to claim 14, wherein a material of the intermediate dielectric layer comprises a silicate nanocomposite material, silicon oxide, derivatives of silicon oxide, silicon oxynitride, silicon carbonitride, polyimide, or benzocyclobutene.

19. The electronic package according to claim 14, wherein a distribution density of the first chip pads is greater than a distribution density of the second chip pads.

20. The electronic package according to claim 14, wherein the bridge element has a plurality of bridge conductive vias, and the chips are electrically connected to the redistribution structure via the bridge conductive vias.

21. The electronic package according to claim 14, further comprising:
a circuit carrier, wherein the sub-package is installed on the circuit carrier.

22. The electronic package according to claim 21. further comprising:
a plurality of conductive balls, connected to the circuit carrier.

23. The electronic package according to claim 14, wherein the bridging pads are respectively directly bonded to the first chip pads.

24. The electronic package according to claim 23, wherein the base dielectric layer does not fill a gap between adjacent two of the bridging pads, and the base dielectric layer does not fill a gap between adjacent two of the first chip pads.

25. The electronic package according to claim 14, wherein each of the chips has a plurality of first pad pillars and a plurality of second pad pillars, the first pad pillars are respectively located on the first chip pads and are surrounded by the base dielectric layer, the second pad pillars are respectively located on the second chip pads and are surrounded by the base dielectric layer, the bridging pads are respectively bonded to the first chip pads via being respectively bonded to the first pad pillars, and the intermediate conductive vias are respectively connected to the second chip pads via being respectively connected to the second pad pillars.
